(19) United States
(12) Patent Application Publication
(10) Pub. No.: US 2008/0262762 A1
(43) Pub. Date: Oct. 23, 2008

(54) POWER TEST DEVICE AND METHOD THEREOF

(75) Inventor: Chun-Wei Ko, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ASUSTeK COMPUTER INC., Taipe (TW)

(21) Appl. No.: 12/105,293

(22) Filed: Apr. 18, 2008

(30) Foreign Application Priority Data
Apr. 20, 2007 (TW) 96113973

(51) Int. Cl. G01R 21/00

(52) U.S. Cl. 702/60

(57) ABSTRACT

A power test device and a method thereof are provided. The power test method includes the following steps. First, a piece of control information is generated by a circuit under test, and a specific voltage and a sensing signal are generated according to the control information. Then, the sensing signal is converted to a piece of scale information, and a piece of power information is obtained by calculating the scale information and is displayed. Therefore, the present invention can obtain the power consumption of the circuit under test without actions such as dismantling a plate and cutting off a conducting wire on the plate.

### CROSS-REFERENCE TO RELATED APPLICATION

This application claims the priority benefit of Taiwan application serial no. 96113973, filed on Apr. 20, 2007. The entirety of the above-mentioned patent application is hereby incorporated by reference herein and made a part of this specification.

### BACKGROUND OF THE INVENTION

1. Field of the Invention

The invention relates to a power test device and a method thereof and, more particularly, to a power test device without externally connecting with a sensing resistance and a method thereof.

2. Description of the Related Art

Along with the continuous progress of the science and technology, various electronic products have continuously weeded through the old to bring forth the new, and especially, the occurrence of computers thoroughly changes the life mode of people. In the computer field, computers have gradually been transformed from desktop computers to portable computers which are short, small, light and slim, such as the notebook personal computer (PC), the pocket PC, the tablet PC, and so on.

In the computer system, the power consumption of the central processing unit (CPU) occupies most power consumption of the whole computer system. The power consumption of the CPU is increased according to the increment of the operation frequency and the operation voltage, and as for the portable computer which mostly utilizes batteries as its power supply device, it is beyond doubt that the power consumption of the CPU is the attention focus and the research subject of each manufacturer.

FIG. 1 is schematic diagram showing a test base plate which is suitable to be applied in the conventional power test method. Please refer to FIG. 1 to research how the conventional technology measures the power consumption of a CPU. A test base plate 100 includes a CPU 101 and a voltage converter 102. Herein, the CPU 101 can transmit a piece of control information to the voltage converter 102. The voltage converter 102 generates a corresponding operation voltage which is used by the CPU 101 according to the control information.

When a test person wants to measure the power consumption of the CPU 101, he usually cuts off the wiring between the CPU 101 and the voltage converter 102 on the test base plate 100 and makes a sensing resistance 103 connected to the wiring in series. And then the test person can measure the current passing the sensing resistance 103 and the voltage across the sensing resistance 103, and the power consumption of the CPU 101 can be calculated out according to the voltage value and the current value obtained in the measuring.

However, the data obtained by the conventional power test method is not the actual power consumption of the CPU 101. Therefore, the test base plate 100 needs to be additionally connected with a sensing resistance in series during the measurement process, and the sensing resistance 103 can affect the accuracy of the measurement data. In this way, the conventional power test method cannot satisfy the precision and accuracy spirit of the science and needs to dismantle the plate and cut off the wire on the plate, so that the conventional power test method is time-consuming and laborious.

### BRIEF SUMMARY OF THE INVENTION

The invention provides a power test method which can obtain the power consumption of a circuit under test without actions such as dismantling a plate, cutting off a conducting wire on the plate and so on.

The invention provides a power test device which can make the power consumption of the circuit under test be directly known via a monitor, and thereby the power management of the system can be projected to obtain the best heat dissipation mechanism of the circuit under test.

The invention provides a power test method including the following steps. Firstly, a piece of control information is generated by a circuit under test. And then, a specific voltage and a sensing signal are generated according to the control information, wherein the specific voltage is used as the operation voltage of the circuit under test. In this way, the sensing signal is converted to a piece of scale information, and a piece of power information is obtained by calculating the scale information and is displayed.

In one embodiment of the invention, when the above control information includes a plurality of voltage control information, the above power test method further includes the following steps. Firstly, one of these voltage control information is selected as a piece of specific voltage control information. And then, in steps a and b, a specific sensing signal is generated according to the selected specific voltage control information and is converted to a piece of scale information. In step c, a piece of specific power information is obtained by calculating the specific scale information.

In this way, in step d, whether these voltage control information have been selected one after another is determined, if these voltage control information has not been selected one after another, one of the voltage control information which has not been selected is reselected to be the specific voltage control information, and step a to step d are repeated; if these voltage control information has been selected one after another, a piece of maximal power information is generated according to the generated a plurality of specific power information and is displayed.

The invention further provides a power test device which includes a circuit under test, a voltage converter, an analog-to-digital (A/D) converter and a monitor. The circuit under test is used to generate a piece of control information. The voltage converter generates a specific voltage and a sensing signal according to the control information, wherein the circuit under test is operated under the specific voltage. And then, the A/D converter converts the sensing signal to a piece of scale information, and the circuit under test receives and calculates the scale information to generate a piece of power information. Finally, the monitor is used to display the power information.

In one embodiment of the invention, the above power test device further includes a test base plate, wherein the voltage converter, the A/D converter and the monitor are provided on the test base plate.

The invention can obtain the power consumption of the circuit under test without actions such as dismantling a plate and cutting off a conducting wire on the plate, and then can effectively improve the conventional power test method which is inconvenient and deficient. In addition, the invention can also obtain the best heat dissipation mechanism of the circuit under test according to the power consumption information of the circuit under test.

These and other features, aspects, and advantages of the present invention will become better understood with regard to the following description, appended claims, and accompanying drawings.

### BRIEF DESCRIPTION OF THE SEVERAL VIEWS OF THE DRAWINGS

FIG. 1 is schematic diagram showing a test base plate which is suitable to be applied in the conventional power test method.

FIG. 2 is a schematic diagram showing a power test device which is used to illustrate the embodiment in FIG. 3.

FIG. 3 is a flow chart showing a power test method according to one embodiment of the invention.

FIG. 4 is a flow chart showing a method of obtaining the best heat dissipation mechanism according to one embodiment of the invention.

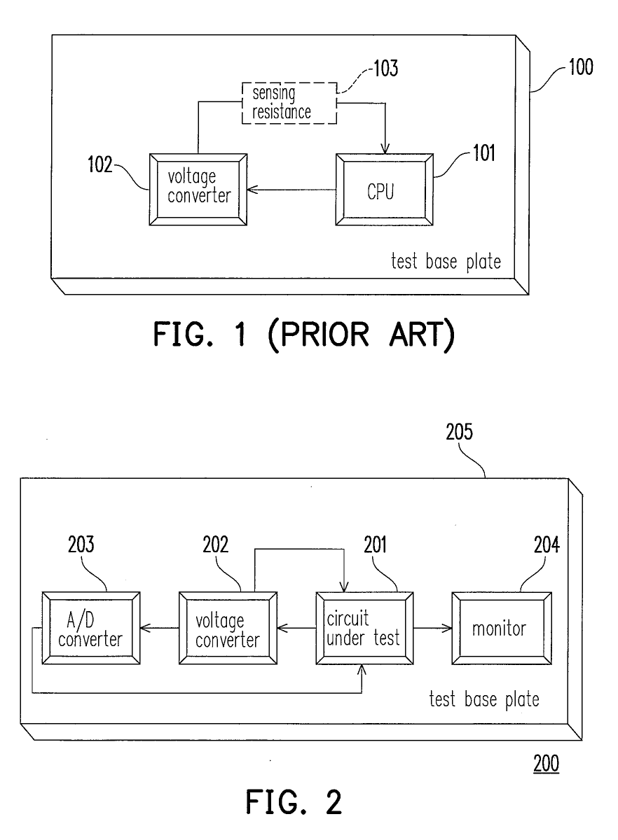

### DETAILED DESCRIPTION OF THE EMBODIMENTS

Before the spirit of the invention is illustrated with embodiments, the power test method of the invention is supposed to be suitable to be applied to a power test device shown in FIG. 2, and the power test device 200 includes a circuit under test 201, a voltage converter 202, an analog-to-digital (A/D) converter 203, a monitor 204 and a test base plate 205. The circuit under test 201, the voltage converter 202, the A/D converter 203 and the monitor 204 are provided on the test base plate 205. The circuit under test 201 is coupled to the voltage converter 202 and the monitor 204, the voltage converter 202 is coupled to the A/D converter 203, and the A/D converter 203 is further coupled to the circuit under test 201.

The above assumption is not used for limiting the scope of the invention, and persons having ordinary skill in the art may make various modifications for the following embodiments according to the spirit of the invention, and various modifications for the following embodiments are all within the scope and spirit of the invention. In addition, the power test method of the invention can be applied to measure the power consumption of a central processing unit (CPU), and therefore, the above test base plate can be a computer motherboard, and the circuit under test can be a CPU. Furthermore, the above voltage converter 202 can be formed with the ISL6260C chip and the ISL6208 chip which are cooperated with each other and are manufactured by Intersil Corporation, or can be formed with the same type of chips which are cooperated with each other and are manufactured by Motorola Corporation, Ti Corporation, Maxim Corporation and so on.

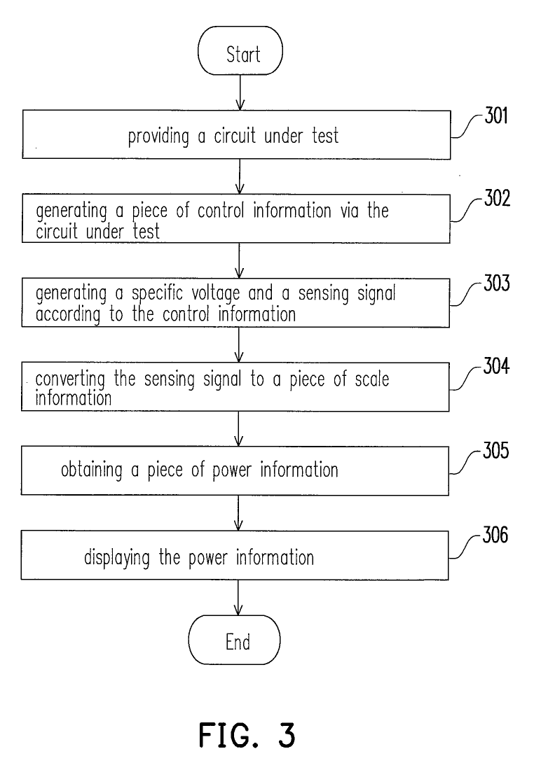

FIG. 3 is a flow chart showing a power test method according to one embodiment of the invention. Please refer to FIG. 2 and FIG. 3 simultaneously. First, a circuit under test 201 is provided and the circuit under test 201 is disposed on the test base plate 200 (step 301). During the process of measuring the power consumption of the circuit under test 201, the circuit under test 201 can generate a piece of control information (step 302) and transmits the control information to the voltage converter 202. After the voltage converter 202 receives the control information, the voltage converter 202 generates a specific voltage and a sensing signal according to the control information (step 303), wherein the specific voltage is transmitted to the circuit under test 201 by the voltage converter 202 to be the operation voltage of the circuit under test 201, and the sensing signal is transmitted to the A/D converter 203.

After the A/D converter 203 receives the sensing signal, it converts the sensing signal to a piece of scale information (step 304) and transmits the scale information to the circuit under test 201. In this way, the circuit under test 201 can receive and calculate the scale information to generate a piece of power information (step 305), and transmit the power information to the monitor 204. Finally, the monitor 204 displays the power information calculated by the circuit under test 210 on the screen in real time, and then the correct power consumption can be quickly known (step 306).

The sensing signal generated by the above voltage converter 202 includes the operation voltage information and the operation current information of the circuit under test 201. That is, in addition to providing the circuit under test 201 with the specific voltage as the operation voltage of the circuit under test 201 according to the received control information, the voltage converter 202 can also detect the operation current of the circuit under test which is operated under the operation voltage. In addition, the voltage converter 202 can also automatically generate a specific formula which is used by the circuit under test 201 to calculate the power. During the process of calculating the scale information, the circuit under test 201 can make an operation for the scale information according to the specific formula that the voltage converter 202 automatically generates, and finally, a piece of power information is obtained according to the operation result. The specific formula generates for example: according to characteristics of the specific voltage and the sensing signal.

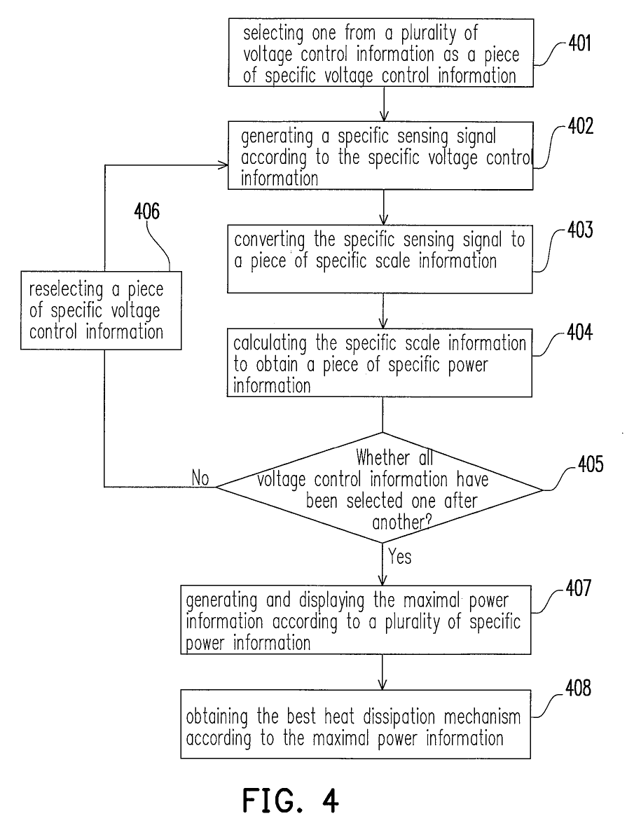

In addition, when the control information generated by the circuit under test 201 includes a plurality of voltage control information, the power test device 200 can obtain the best heat dissipation mechanism according to these voltage control information. For example, FIG. 4 is a flow chart showing a method of obtaining the best heat dissipation mechanism according to one embodiment of the invention. Please refer to FIG. 4. When the control information generated by the circuit under test 201 includes a plurality of voltage control information, first, the circuit under test 201 can select one from these voltage control information as a piece of specific voltage control information (step 401) and output the voltage control information to the voltage converter 202.

After the voltage converter receives the voltage control information, the voltage converter 202 generates a corresponding specific sensing signal according to the received voltage control information (step 402) and outputs the specific sensing signal to the A/D converter 203. After the A/D converter 203 receives the specific sensing signal, the A/D converter 203 can convert the specific sensing signal to a piece of specific scale information (step 403) and transmit the specific scale information to the circuit under test 201. In this way, the circuit under test 201 can make an operation for the received specific scale information according to the specific formula that the voltage converter 202 automatically generates to obtain a piece of specific power information (step 404).

After obtaining a piece of specific power information, at this time, the circuit under test 201 can determine whether all voltage control information has been selected one after another (step 405). If not all voltage control information has been selected one after another, the circuit under test 201 will select one from the voltage control information which has not been selected to be the specific voltage control information (step 406). Steps 402-404 are performed again to obtain another piece of specific power information after the specific voltage control information is re-obtained. In other words, during repeatedly performing the steps 402-406, the circuit under test 201 can obtain a plurality of specific power information according to a plurality of voltage control information.

Relatively, when the circuit under test 201 determines that all voltage control information has been selected one after another, that is, when the circuit under test 201 obtains a plurality of specific power information according to a plurality of voltage control information, the circuit under test 201 will compare these specific power information to obtain the maximal power information which will be displayed on the screen in real time via the monitor 204 (step 407). Finally, the power test device 200 obtains the maximal power consumption of the circuit under test according to the maximal power information. On the power distribution, the power test device 200 can also determine the working state (busy or idle) of the circuit under test 201 according to the maximal power information further to obtain the best heat dissipation mechanism of the circuit under test 201 by adjusting the heat dissipation mode of the circuit under test 201 (step 408).

To sum up, the invention mostly utilizes the voltage control information generated by a circuit under test to obtain the actual power consumption of the circuit under test. Compared with the conventional technology, the invention can obtain the power consumption of the circuit under test without the actions such as dismantling a plate and cutting off a conducting wire on the plate. In other words, the invention can effectively improve the conventional power test method which is inconvenient and deficient.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A power test method comprising the steps of:
generating a piece of control information via a circuit under test;
generating a specific voltage and a sensing signal according to the control information;
converting the sensing signal to a piece of scale information;
calculating the scale information and obtaining a piece of power information according to the calculation result; and
displaying the power information.

2. The power test method according to claim 1 further comprising the step of providing the circuit under test.

3. The power test method according to claim 1, wherein the specific voltage is the operation voltage of the circuit under test.

4. The power test method according to claim 1, wherein the circuit under test comprises a central processing unit (CPU).

5. The power test method according to claim 1, wherein the step of calculating the scale information and obtaining a piece of power information according to the calculation result comprises the steps of:
generating a specific formula according to characteristics of the specific voltage and the sensing signal; and
calculating the scale information according to the specific formula to generate the power information by the circuit under test.

6. The power test method according to claim 1, wherein when the control information comprises a plurality of voltage control information, the power test method further comprises the steps of:
selecting one from the voltage control information as a piece of specific voltage control information;
a. generating a specific sensing signal according to the voltage control information;
b. converting the specific sensing signal to a piece of specific scale information;
c. calculating the specific scale information to obtain a piece of specific power information;
d. determining whether the voltage control information has been selected one after another, reselecting one from the voltage control information which has not been selected as the specific voltage control information and repeating step a to step d if the voltage control information has not been selected one after another, and generating and displaying a piece of maximal power information according to the specific power information if the voltage control information has been selected one after another.

7. The power test method according to claim 6 further comprising the step of:
obtaining the best heat dissipation mechanism of the circuit under test according to the maximal power information.

8. A power test device comprising:
a circuit under test for generating a piece of control information;
a voltage converter for generating a specific voltage and a sensing signal according to the control information, wherein the circuit under test is operated under the specific voltage;
an analog-to-digital (A/D) converter for converting the sensing signal to a piece of scale information, wherein the circuit under test receives and calculates the scale information to generate a piece of power information; and
a monitor for displaying the power information.

9. The power test device according to claim 8 further comprising a test base plate, wherein the voltage converter, the A/D converter and the monitor are provided on the test base plate.

10. The power test device according to claim 8, wherein the circuit under test comprises a CPU.
